(19) United States
(12) Patent Application Publication
(10) Pub. No.: US 2009/0257263 A1
(43) Pub. Date: Oct. 15, 2009

(54) Method and Apparatus for Computer Memory

(75) Inventor: Charles H. Moore, Sierra City, CA (US)

Correspondence Address: HENNEMAN & ASSOCIATES, PLC, 70 N. MAIN ST., THREE RIVERS, MI, 49093, US

(73) Assignee: VNS PORTFOLIO LLC, Cupertino, CA (US)

(21) Appl. No.: 12/243,764

(22) Filed: Oct. 1, 2008

Related U.S. Application Data
(60) Provisional application No. 61/124,174, filed on Apr. 15, 2008.

(51) Int. Cl. G11C 5/06; H01S 4/00

(52) U.S. Cl. 365/63; 29/592.1

(57) ABSTRACT

A method and apparatus for forming computer memory 10 including RAM, ROM, Stacks and other registers. The memory array 10 includes a number of individual memory cells 40, 42, 44, 46 connected to each other by word lines 18, 20 and bit lines 30, 32. Memory cells 40, 42, 44, 46 word lines 18, 20 and bit lines 30, 32 are oriented in a manner to provide minimum line length and a substantialy square geometry. The method includes arranging the memory cells in an interleaved formation.

### CROSS-REFERENCE TO RELATED APPLICATIONS

This application claims the benefit of U.S. Provisional Patent Application Ser. No. 61/124,174 entitled “Improvements for a Computer Array Chip”, filed on Apr. 15, 2008, which is incorporated herein by reference in its entirety.

### BACKGROUND OF THE INVENTION

1. Field of the Invention

The present invention relates to the field of computers and computer processors, and more particularly to an improved memory layout on a microchip, especially in multiprocessor arrays in single-chip embedded systems.

2. Description of the Background Art

Multiple computer processors are frequently used working together, to accomplish a task. It is a trend now to combine several processors on a single chip, and now it is thought that, for a number of reasons, the best arrangement of multiple processors for many applications might be an array consisting of many computers, each having processing capabilities and at least some dedicated memory. In such an example, the computers will each not be particularly powerful in their own right, but rather the computing power will be achieved through close cooperation of the computers. An example of a known single-chip multiprocessor array comprising a plurality of computers wherein the inventive interleaved memory can be used is the SEAforth®-24A Embedded Array Processor described in SEAforth®-24A Embedded Array Processor Device Data Sheet (Preliminary Version 1.1, Mar. 7, 2008) published by IntellaSys®, hereinafter referred to as Data Sheet. An 18-bit word size is employed in the SEAforth® computers, and in one version, the RAM size can be 128 words.

Clearly there are many questions to be answered regarding how best to arrange the circuits of such computer arrays. Some of these questions may have been answered, but there may well be room for improvement even over the existing solutions. It is desirable, especially in multiprocessor arrays used in single-chip embedded systems wherein area on the chip is at a premium, to employ a layout with minimum area to accomplish a given circuit function. This can result in a circuit that is otherwise highly effective but has a feature, which, under some conditions, can be undesirable. One such feature is the low aspect ratio of optimum on-chip computer memory layout. A semiconductor random access memory, also known as RAM, or a read-only memory, also known as ROM, as depicted in FIG. 1 by a memory portion 100, typically includes a plurality of memory cells 102 which are typically disposed in a two-dimensional array with a plurality of rows and columns, and are electrically accessed though two mutually orthogonal arrays of wires termed word lines 104 and bit lines 106, which are disposed parallel to the rows and columns, respectively, each cell being connected to a word line, for example by a word select wire 108 and to a bit line, by a read or write wire 110. Although one bit line is shown per memory cell, two bit lines are often employed, for differential reading, or for separation of read and write circuits. The width of a row conventionally includes a number of cells that corresponds to the number of bits in one word, a word being the basic unit of binary data handled by the computer, and the size of a memory conventionally specifies the number of words that can be stored. A typical memory access operation is performed sequentially by row and simultaneously, in parallel, for a plurality of columns so that, for example, all bits of a multi-bit word can be read or written at the same time. A relatively small memory, such as a buffer, cache, or local memory of a computer in a single-chip embedded multiprocessor array, is often one word wide in its physical layout on the chip, and has straight bit lines, in order to reduce the area lost to bends in bit lines. Memory portion 100 can accordingly represent portions of three words 112, 114, 116 of such a memory. As the number of words of memory provided often exceeds the word size, the resulting memory layout has a smaller width (i.e., number of bits) than height (i.e., number of words), and thus can be referred to as having a low aspect ratio. An example of a conventional memory layout outline 200 for a 128-word memory with 18-bit word size, assuming approximately square memory cells, is illustrated in FIG. 2, showing a low aspect ratio of 18/128≈0.14. It should be noted that in this and also in other layout outline figures that will be presented hereinafter, the width and height of a layout, in terms of the number of memory cells, is indicated as a multiplication, for example “18×128”.

However, for a number of reasons including better mechanical integrity of the resulting chip and lower parasitic impedances of lines on the chip, a higher aspect ratio closer to unity, i.e., a squarer layout is desirable. A known technique to avoid low aspect ratio is a folded layout 210, shown in FIG. 3 for the same size memory, wherein the memory cells are divided into two portions 212, 214 of 64 words each, disposed side-by-side and connected by folded (bent) bit lines 216. A disadvantage of such a folded layout is that some area on the chip is required for bends in the bit lines, which in this example is approximately identified as the region between the brackets 218 shown in FIG. 3. This adds complication and is especially undesirable in embedded single-chip multiprocessor applications, where chip area can be scarce.

A need exists, therefore, for an improved memory layout with straight bit lines and lower aspect ratio.

### SUMMARY OF INVENTION

Accordingly, it is an object of the present invention to provide for a computer memory layout with straight bit lines and higher aspect ratio than a one-word-wide memory.

The present invention provides an improved computer memory layout with straight bit lines and two words per row of memory cells, wherein successive words are grouped into pairs, and the memory cells of each pair are spatially interleaved into one row, thereby providing a larger aspect ratio.

### BRIEF DESCRIPTION OF THE FIGURES

In the accompanying drawings:

FIG. 1 is a symbolic block diagram of prior art computer memory layout showing conventional disposition of memory cells, word lines, and bit lines;

FIG. 2 is a symbolic diagram of prior art computer memory layout outline with low aspect ratio;

FIG. 3 is a symbolic diagram of prior art folded memory layout outline;

FIG. 4 is a symbolic block diagram of an interleaved memory according to an embodiment of the invention, showing disposition of memory cells, word lines, and bit lines; and

FIG. 5 is a symbolic diagram of an interleaved memory layout outline of a 128-word, 18-bits per word RAM, according to an embodiment of the invention.

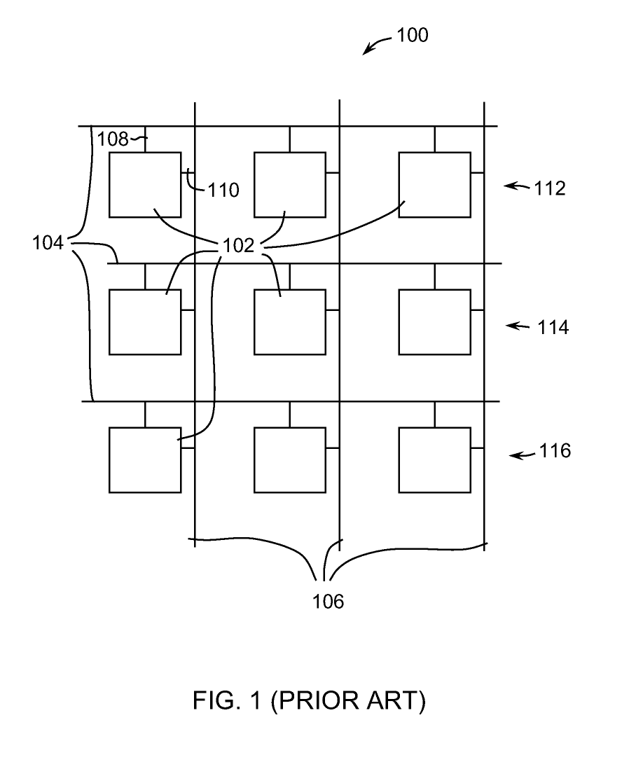

### DETAILED DESCRIPTION

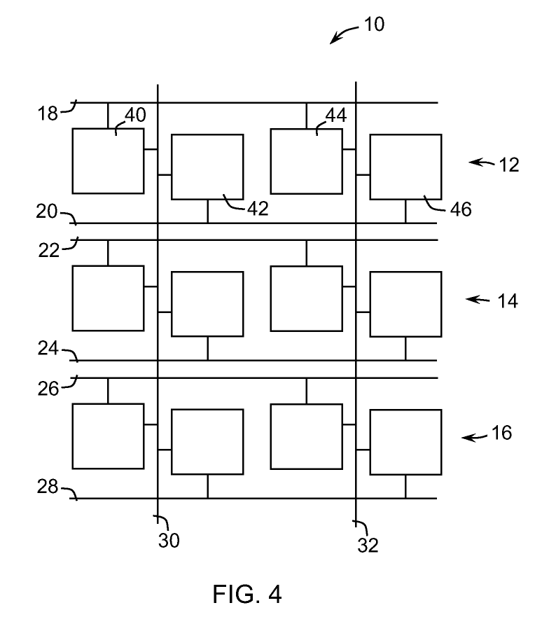

A first mode for carrying out the invention is an interleaved computer memory wherein the memory cells of adjacent pairs of words are spatially interleaved and disposed substantially in one row. A portion of the inventive interleaved memory is depicted in symbolic block diagram view in FIG. 4 and is designated therein by the general reference character 10. According to an embodiment of the invention, a row of interleaved memory is two words wide, that is, the number of memory cells in a row is twice the number of bits per word. The memory portion 10, which can be, for example RAM and alternatively ROM, includes portions of six words of memory disposed in three rows 12, 14, 16, the cells of which are connected to six word lines 18, 20, 22, 24, 26, 28, and also to two bit lines 30, 32. In the interleaved memory layout, word lines are grouped into pairs 18 and 22, 20 and 22, and 24 and 26, and memory cells connecting to a pair are spatially interleaved and connected to word lines and bit lines from opposite sides, as shown in FIG. 4. For example, cells 40, 44 connect to word line 18 from “below” and are interleaved along row 12 with cells 42, 46, which connect to word line 20 from “above”. Further, adjacently disposed cells 40, 42 connect to bit line 30 from “left” and “right” respectively, i.e., from opposite sides; and adjacent cells 44, 46 connect to bit line 32 likewise from opposite sides. It should be noted that the words “above”, “below”, “left”, and “right” are used herein to designate relative direction in two dimensions, as on the surface of a semiconductor chip, and not absolute direction with respect to gravity or other fixed coordinates.

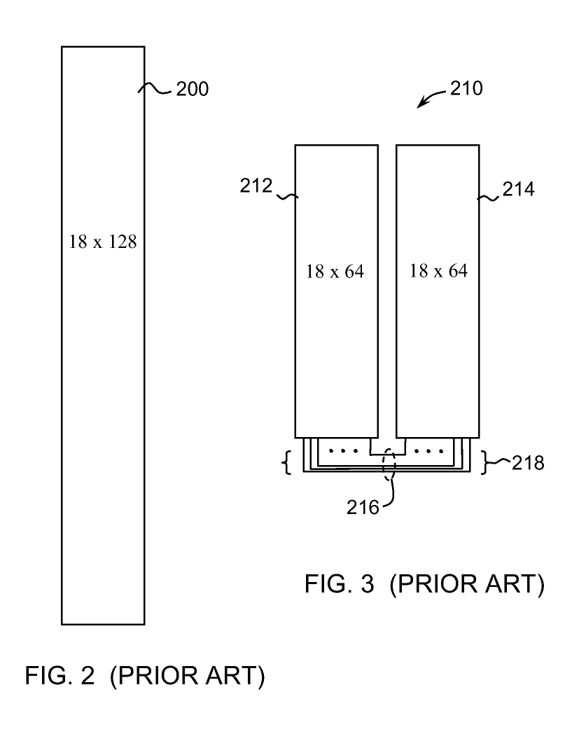

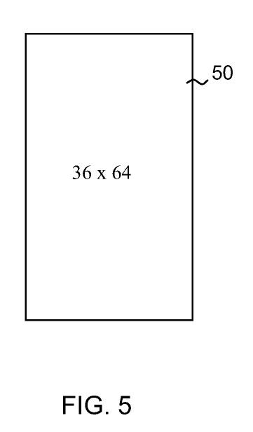

A second embodiment of the invention is shown in FIG. 5. The layout outline 50 of an embodiment of the inventive interleaved memory suitable for the RAM of a SEAforth® computer, is shown in FIG. 5. It will be apparent, with reference to the layout outline 200 of a similar size one-word-wide memory shown in FIG. 2, that the interleaved memory 50 has a significantly improved aspect ratio.

In some cases of computer memory circuit layout, there can be a need for bit lines to be spaced wider that a memory cell width; for example, to accommodate other circuits such as pass gates. In such cases, the interleaved memory layout, according to the invention, will be further advantageous in packing more cells into a given layout area.

### INDUSTRIAL APPLICABILITY

The inventive memory arrays 10, 40, 42, 44, 46 word lines 18, 20, bit lines 30, 32 and method are intended to be widely used in a great variety of computer applications. It is expected that they will be particularly useful in applications where significant computing power is required, and yet power consumption and heat production are important considerations.

As discussed previously herein, the applicability of the present invention is such that the sharing of information and resources between the computers in an array is greatly enhanced, both in speed a versatility. Also, communications between a computer array and other devices is enhanced according to the described method and means. The inventive memory arrays 10, 40, 42, 44, 46 word lines 18, 20, bit lines 30, 32 and method of the present invention may be readily produced and integrated with existing tasks, input/output devices, and the like; and since the advantages as described herein are provided, it is expected that they will be readily accepted in the industry. For these and other reasons, it is expected that the utility and industrial applicability of the invention will be both significant in scope and long-lasting in duration.

1. A method for making computer memory comprised of memory cells on bit and word lines comprising the steps of, situating memory cells into lines; and interleveing memory cells.

2. A method for making computer memory as in claim 1, comprising the further step of aligning the memory cells so that the bit lines are substantially straight.

3. A method for making computer memory as in claim 2, comprising the further step of connecting adjacent cells to different bit lines.

4. A method for making computer memory as in claim 1, comprising the further step of aligning the memory cells so that the word lines are substantially straight.

5. A method for making computer memory as in claim 4, comprising the further step of connecting adjacent cells to different word lines.

6. A method for making computer memory as in claim 5, comprising the further step of aligning the memory cells so that the bit lines are substantially straight.

7. A method for making computer memory as in claim 6, comprising the further step of connecting adjacent cells to different bit lines.

8. A memory for a computer comprising: a plurality of interleaved memory cells; and a plurality of substantially straight bit lines connected to the memory cells for conveying information to and from the memory cells; and a plurality of substantially straight word lines connecting the memory cells for forming groups of memory cells.

9. A memory for a computer as in claim 8, further comprising; a first bit line, and a second bit line, wherein the memory cells are interleaved by having opposite sides of the adjacent memory cells connected to the word lines.

10. A memory for a computer as in claim 8, wherein the memory cells are interleaved by having the adjacent memory cells connected to different word lines.

11. A memory for a computer as in claim 10, further comprising; a first bit line and a second bit line, wherein the memory cells are interleaved by having opposite sides of the adjacent memory cells connected to the word lines.

12. A memory for a computer as in claim 9, wherein the bit lines are substantially straight.

13. A memory for a computer as in claim 11, wherein the bit lines are substantially straight.

14. An improved memory array for a computer having a plurality of memory cells and a plurality of bit lines and a plurality of word lines, the improvement comprising interweaving the memory cells to allow substantially straight bit lines and word lines.

15. An improved memory array for a computer as in claim 14, wherein said memory array is a Read Only Memory (ROM).

16. An improved memory array for a computer as in claim 14, wherein said memory array is a Random Access Memory (RAM).

17. An improved memory array for a computer as in claim 14, wherein said memory array is a memory stack and said computer is a stack computer.

18. An improved memory array for a computer as in claim 14, wherein said memory cells are interleaved by having opposite sides of the adjacent memory cells connected to said word lines.
